(19) United States
(12) Patent Application Publication
(10) Pub. No.: US 2008/0026302 A1
(43) Pub. Date: Jan. 31, 2008

(54) BLACK MATRIX COMPOSITIONS AND METHODS OF FORMING THE SAME

(76) Inventors: Quanyuan Shang, Saratoga, CA (US); Ligui Zhou, Dublin, CA (US)

Correspondence Address: DUGAN & DUGAN, PC, 245 Saw Mill River Road, Suite 309, Hawthorne, NY, 10532, US

(21) Appl. No.: 11/733,665

(22) Filed: Apr. 10, 2007

Related U.S. Application Data
(60) Provisional application No. 60/834,076, filed on Jul. 28, 2006.
(60) Provisional application No. 60/823,254, filed on Aug. 23, 2006.

(51) Int. Cl. G03F 1/00; G03C 1/00

(52) U.S. Cl. 430/7; 430/286.1

(57) ABSTRACT

Black matrix compositions, methods for forming a black matrix, and apparatus for use in forming a color filter for a flat-panel display are disclosed. The compositions, methods and apparatus use an additive including polymerizable molecules, the polymerizable molecules each including polar portions and non-polar portions. The non-polar portions are ink-phobic and migrate toward the surface of the black matrix composition upon the surface being exposed to activation energy. The polar portions of the polymerizable molecules are ink-philic relative to the non-polar portions. Numerous other features are disclosed.

The present application claims priority to:

U.S. patent application Ser. No. 11/521,577, filed Sep. 13, 2006 and entitled “METHOD AND APPARATUS FOR MANUFACTURING A PIXEL MATRIX OF A COLOR FILTER FOR A FLAT PANEL DISPLAY,” (Attorney Docket No. 10502) which claims priority to U.S. Provisional Patent Application Ser. No. 60/718,565, filed Sep. 19, 2005 and entitled “METHOD AND APPARATUS FOR MANUFACTURING A PIXEL MATRIX OF A COLOR FILTER FOR A FLAT PANEL DISPLAY,” (Attorney Docket No. 10502/L);

U.S. Provisional Patent Application Ser. No. 60/834,076, filed Jul. 28, 2006 and also entitled “METHOD AND APPARATUS FOR MANUFACTURING A PIXEL MATRIX OF A COLOR FILTER FOR A FLAT PANEL DISPLAY,” (Attorney Docket No. 10502/L2); and

U.S. Provisional Patent Application Ser. No. 60/823,254, filed Aug. 23, 2006 and entitled “BLACK MATRIX COMPOSITIONS AND METHODS OF FORMING THE SAME,” (Attorney Docket No. 11292/L), all four of which are hereby incorporated herein by reference in their entirety for all purposes.

### CROSS-REFERENCE TO RELATED APPLICATIONS

The present application is related to the following commonly-assigned, co-pending U.S. Patent Applications, each of which is hereby incorporated herein by reference in its entirety for all purposes:

U.S. Provisional Patent Application Ser. No. 60/625,550, filed Nov. 4, 2004 and entitled “APPARATUS AND METHODS FOR FORMING COLOR FILTERS IN A FLAT PANEL DISPLAY BY USING INKJETTING”;

U.S. patent application Ser. No. 11/019,967, filed Dec. 22, 2004 and entitled “APPARATUS AND METHODS OF AN INKJET HEAD SUPPORT HAVING AN INKJET HEAD CAPABLE OF INDEPENDENT LATERAL MOVEMENT” (Attorney Docket No. 9521-1);

U.S. patent application Ser. No. 11/019,929, filed Dec. 22, 2004 and titled “METHODS AND APPARATUS FOR INKJET PRINTING.” (Attorney Docket No. 9521-2);

U.S. patent application Ser. No. 11/019,930, filed Dec. 22, 2004 and entitled “METHODS AND APPARATUS FOR ALIGNING PRINT HEADS” (Attorney Docket No. 9521-3);

U.S. Provisional Patent Application Ser. No. 60/703,146, filed Jul. 28, 2005 and entitled “METHODS AND APPARATUS FOR SIMULTANEOUS INKJET PRINTING AND DEFECT INSPECTION” (Attorney Docket No. 9521-L02 (formerly 9521-7/L); and

U.S. patent application Ser. No. 11/493,861, filed Jul. 25, 2006 and entitled “METHODS AND APPARATUS FOR CONCURRENT INKJET PRINTING AND DEFECT INSPECTION” (Attorney Docket No. 9521-10)

### FIELD OF THE INVENTION

The present invention relates to flat panel displays, and more particularly to black matrix compositions for use with flat panel displays, and methods of forming the same.

### BACKGROUND

The flat panel display industry has been attempting to employ inkjet printing to manufacture display devices, in particular, color filters. One problem with effective employment of inkjet printing is that it is difficult to inkjet ink or other material accurately and precisely onto a substrate while having high throughput. In some cases, for example, ink drops may not land precisely within pixel wells on the substrate. What is needed are methods and apparatus to improve the quality of color filters manufactured using high throughput inkjet printing.

### SUMMARY OF THE INVENTION

In certain aspects of the invention, a black matrix composition for use in forming a color filter for a flat-panel display is provided that includes an additive with polymerizable molecules, the polymerizable molecules each including polar portions and non-polar portions. The non-polar portions are ink-phobic and migrate toward the surface of the black matrix composition upon the surface being exposed to activation energy. The polar portions of the polymerizable molecules are ink-philic relative to the non-polar portions. The result when used to form a pixel matrix is a structure having an ink-phobic top surface and ink-philic sidewall surfaces.

In other aspects of the invention, an apparatus for use in forming a color filter for a flat-panel display is provided that includes a substrate and a layer of black matrix composition formed on the substrate. The black matrix composition includes an additive with polymerizable molecules, the polymerizable molecules each including polar portions and non-polar portions. The non-polar portions are ink-phobic and migrate toward the surface of the black matrix composition upon the surface being exposed to activation energy. The polar portions of the polymerizable molecules are ink-philic relative to the non-polar portions.

In yet other aspects of the invention, a method of forming a color filter for a flat-panel display is provided. The method includes forming a black matrix composition including polymerizable molecules, the polymerizable molecules each including polar portions and non-polar portions; providing a substrate; forming a layer of the black matrix composition on the substrate; and applying activation energy to the black matrix composition on the substrate. The non-polar portions are ink-phobic and migrate toward the surface of the black matrix composition in response to applying activation energy to the surface of the black matrix composition. The polar portions of the polymerizable molecules are ink-philic relative to the non-polar portions.

Other features and aspects of the present invention will become more fully apparent from the following detailed description, the appended claims and the accompanying drawings.

### BRIEF DESCRIPTION OF THE DRAWINGS

FIG. 1 is a flow chart depicting an example method according to some aspects of the present invention.

FIG. 2 is a magnified, cross-sectional schematic view of a portion of an example substrate coated with a black matrix composition according to some aspects of the present invention.

FIG. 3 is a magnified, cross-sectional schematic view of a portion of an example masked substrate coated with a black matrix composition being exposed to energy according to some aspects of the present invention.

FIG. 4 is a magnified, cross-sectional schematic view of a portion of an example black matrix pixel well according to some aspects of the present invention.

FIG. 5 is a magnified, cross-sectional schematic view of a portion of an example black matrix pixel well with an ink phobic top surface and ink-philic sidewall surfaces according to some aspects of the present invention.

FIG. 6 is a magnified, cross-sectional schematic view of a portion of a black matrix pixel well filled with ink according to some aspects of the present invention.

FIG. 7 is a magnified schematic representation of a polymerizable additive molecule having an ink-philic polar portion and an ink-phobic non-polar portion according to some aspects of the present invention.

FIG. 8 is a magnified schematic representation of polymerizable additive molecules in a black matrix composition prior to application of activation energy according to some aspects of the present invention.

FIG. 9 is a magnified schematic representation of polymerizable additive molecules in a black matrix composition subsequent to application of activation energy according to some aspects of the present invention.

FIG. 10 is a structural formula of an example wetting additive with a non-polar tail portion according to some aspects of the present invention.

FIG. 11 is a structural formula of an example wetting additive with a non-polar body portion according to some aspects of the present invention.

FIG. 12 is a structural formula of an example silicon polymer wetting additive according to some aspects of the present invention.

### DETAILED DESCRIPTION

Flat panel display manufacturing may use color filters that include different colored inks printed on a glass (or other material) substrate. The ink may be deposited using an inkjet printer adapted to precisely jet ink and/or other suitable material directly into specific pixel wells defined by a pixel matrix (typically referred to as a “black matrix”). Before the ink is deposited, the black matrix of pixel wells may be formed on the substrate using lithography or any suitable process.

Materials in contact with liquid have an attractive or repulsive response to the liquid. The material's composition, its corresponding surface chemistry, and the chemistry of the liquid determine the interaction with the liquid. This phenomenon is termed hydrophilicity (analogously e.g., ink-philicity for liquid ink) and hydrophobicity (analogously e.g., ink-phobicity for liquid ink).

Hydrophilicity, also called hydrophilic, is a characteristic of materials exhibiting an affinity for water. Hydrophilic literally means “water-friendly” and such materials readily adsorb water. The surface chemistry allows these materials to be wetted forming a liquid film or coating on their surface. Hydrophilic materials also possess a high surface tension value and have the ability to form bonds with water.

Hydrophobicity, also termed hydrophobic, is a characteristic of materials that have the opposite response to water interaction compared to hydrophilic materials. Hydrophobic materials (“water fearing”) have little or no tendency to adsorb water and water tends to “bead” on their surfaces (i.e., form discrete droplets). Hydrophobic materials possess low surface tension values and lack active groups in their surface chemistry for formation of bonds with water.

Note that in some cases, a single material may be “philic” relative to a liquid that, for example, is water-based and “phobic” relative to a liquid that, for example, is oil based, or vice versa. The words hydrophilicity, ink-philicity, hydrophobicity, and ink-phobicity as used herein are intended as relative terms and a material may be ink-phobic to some inks and ink-philic to other inks. Further, just because a material is hydrophobic does not mean that the material is ink-phobic. Likewise, just because a material is hydrophilic does not mean that the material is ink-philic. Thus, for example, a material may be hydrophobic and ink-philic at the same time or hydrophilic and ink-phobic at the same time because, e.g., an ink maybe oil-based or water-based.

Wettability refers to a surface property characteristic for materials which yields a value for each compound. Wetting is the contact between a fluid and a surface, when the two are brought into contact. When a liquid has a high surface tension (strong internal bonds), it will form a droplet, whereas a liquid with low surface tension will spread out over a greater area (bonding to the surface). On the other hand, if a surface has a high surface energy (or surface tension), a drop will spread, or wet, the surface. If the surface has a low surface energy, a droplet will form. This phenomenon is a result of the minimization of interfacial energy. If the surface is high energy, it will want to be covered with a liquid because this interface will lower its energy, and so on. The surface tension value of a material can be utilized to determine wettability of a material by specific liquids. Through the measurement of the contact angle between a solid surface and a droplet of liquid on the surface, the surface tension for the solid material can be calculated.

Surface tension (or energy) refers to a force which results from an unbalance in molecular forces that occurs when two different materials (e.g., a liquid droplet on a solid surface) are brought into contact with each other forming an interface or boundary. The force is due to the tendency for all materials to reduce their surface area in response to the unbalance in molecular forces that occurs at their points of contact. The result of this force will vary for different systems of liquids and solids, which dictates the wettability and contact angle between the drop and surface.

For a given droplet on a solid surface the contact angle is a measurement of the angle formed between the surface of a solid and the line tangent to the droplet radius from the point of contact with the solid. The contact angle is related to the surface tension by Young's equation through which the behavior of specific liquid-solid interactions can be calculated. A contact angle of zero results in wetting, while an angle between zero degrees and ninety degrees results in spreading of the drop (due to molecular attraction). Angles greater than ninety degrees indicate the liquid tends to bead or shrink away from the solid surface. A contact angle of 90° or greater generally characterizes a surface as not-wettable, and one less than 90° means that the surface is wettable. In the context of water, a wettable surface may also be termed hydrophilic and a non-wettable surface hydrophobic. Likewise, in the context of ink, a wettable surface may also be termed ink-philic and a non-wettable surface ink-phobic. Superphobic surfaces have contact angles greater than 150°, showing almost no contact between the liquid drop and the surface. This is sometimes referred to as the “Lotus effect.” This characteristic of spreading out over a greater area is sometimes called ‘wetting action.’

Due to variations in the ink-philicity/ink-phobicity of the substrate and/or the material used to form a black matrix, the cross-sectional profile (e.g., the distribution) of the ink drops deposited into the pixel wells may not be optimal for forming color filters. In some cases, the uneven distribution of ink within a pixel well may result in a defect in the color filter.

Generally, a black matrix is formed from a composition that includes a pigment dispersion additive, an initiator, a polymerizable monomer or oligomer or combination thereof (e.g., a photo-polymerizable monomer, thermal-polymerizable monomer, etc.), a binder resin, an epoxy-based monomer, and a solvent. The present methods and apparatus provide black matrix compositions that further include a wetting additive that improves the wetting properties of a black matrix. For example, in some embodiments, the wetting additive may increase the ink-phobicity of top planar surfaces of the black matrix, surfaces such as the top of each pixel well, while altering (e.g., reducing) the ink-phobicity (or altering (e.g., increasing) the ink-philicity) of sidewall surfaces of each pixel well defined by the black matrix. Such a black matrix composition may reduce intermixing of color inks during inkjetting and improve the distribution of ink within each pixel well, improving the fill profiles and the color contrast of the color filter. More specifically, ink that inadvertently lands on the top surface of the pixel matrix will fall into the pixel wells and better wet the sidewalls. This tendency of the ink to fall into and spread out in the pixel wells of the present invention reduces the accuracy or precision required of the printer in distributing ink.

In one or more embodiments, the wetting additive may include any material that has polymerizable molecules that each has both a relatively ink-philic polar portion and a relatively ink-phobic non-polar portion. For example, such a material may include one or more hydrophobic-group-contained monomers and/or oligomers such as fluorinated acrylate monomers and/or oligomers; silicone-group-contained acrylate monomers or oligomers, other acrylate monomers and/or oligomers; reactive wax; and/or fluorosilanes. Polymerization is a process of reacting monomer and/or oligomer molecules together in a chemical reaction to form three-dimensional networks or polymer chains. As described further below, these wetting additives may be employed in lieu of, for example, an epoxy-based monomer, and “activated” by a curing step that concentrates the ink-phobic end of the additive's molecules at the top surface of the black matrix. Upon patterning, a black matrix having ink-phobic planar pixel well (top) surfaces and ink-philic (e.g., relative to the top planar surfaces of the black matrix) pixel well sidewall surfaces may be formed.

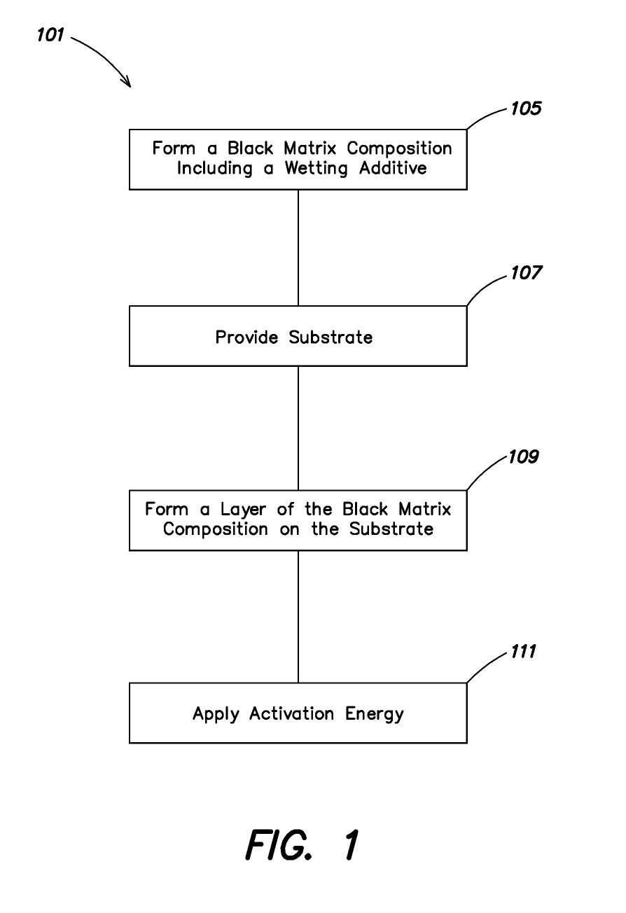

Exemplary black matrix compositions, methods of forming the same, and methods of manufacturing a black matrix in accordance with the present invention are described below with reference to FIGS. 1 to 12. For example, FIG. 1 illustrates a method 101 of manufacturing a black matrix on a substrate in accordance with an embodiment of the present invention. With reference to FIG. 1, in step 105, a black matrix composition including a wetting additive may be formed. For example, the black matrix composition may include a wetting additive such as a hydrophobic-group-contained monomer or oligomer (e.g., a fluorinated acrylate monomer or oligomer, a silicone-group-contained acrylate monomer or oligomer, an other-group-contained acrylate monomer or oligomer, etc.)

The black matrix composition may include other components such as, for example, a pigment dispersion, an initiator (e.g., a photo-initiator), a polymerizable monomer, a binder resin, a solvent, etc. A pigment dispersion is included to disperse a pigment (e.g., carbon black) throughout the black matrix composition. An initiator is included to help the polymerization reaction (e.g., photo-polymerization reaction, thermal polymerization reaction, or other practicable reaction). A polymerizable monomer (or oligomer) may be included to polymerize the composition to form the black matrix. Examples of such molecules include acrylate monomers/oligomers, epoxy monomers/oligomers, etc. A binder resin may be included to give the black matrix structure, stiffness, and strength. An example of such a binder resin includes acrylate binder. A solvent may be included to temporarily (e.g., until the solvent evaporates) lower the composition's viscosity to aid in applying the composition to the substrate (e.g., using a spin coating or slit coating method). Examples of such solvents include propylene glycol monomethyl ether acetate (PGMEA) or any suitable solvent such as organic solvents.

In at least some embodiments, the black matrix composition may include the wetting additive (that includes polymerizable molecules that have both an ink-philic polar portion and an ink-phobic non-polar portion) in a concentration of about 100 to about 10,000 parts per million (ppm) by weight of the total composition not including solvent. In some embodiments, the concentration of the wetting additive may preferably be in the range of about 500 ppm to 5,000 ppm by weight of the total composition not including solvent. However, a different concentration range of the wetting additive may be employed. Additional exemplary wetting additives include one or more of CN4000, CN9800, CN990 manufactured by Sartomer Company Inc. of Exton, Pa., TEGO® Rad 2000 Series (e.g., 2200n, 2350 and/or the like), TEGO® Glide Series and/or TEGO® Flow Series manufactured by Degussa AG of Dusseldorf, Germany or the like. However, one or more additional and/or different additives may be employed.

Selection of an appropriate wetting additive may be based on, for example, the molecular weight, hydrophobic group concentration, reactivity, etc., of the wetting additive. In some embodiments, the wetting additive may have a molecular weight in the range of about 100 Mw to about 100,000 Mw (weight average molecular weight). The weight average molecular weight may preferably be in the range of 500 Mw to 10,000 Mw. Although wetting additives with a larger or smaller and/or different molecular weight may be employed.

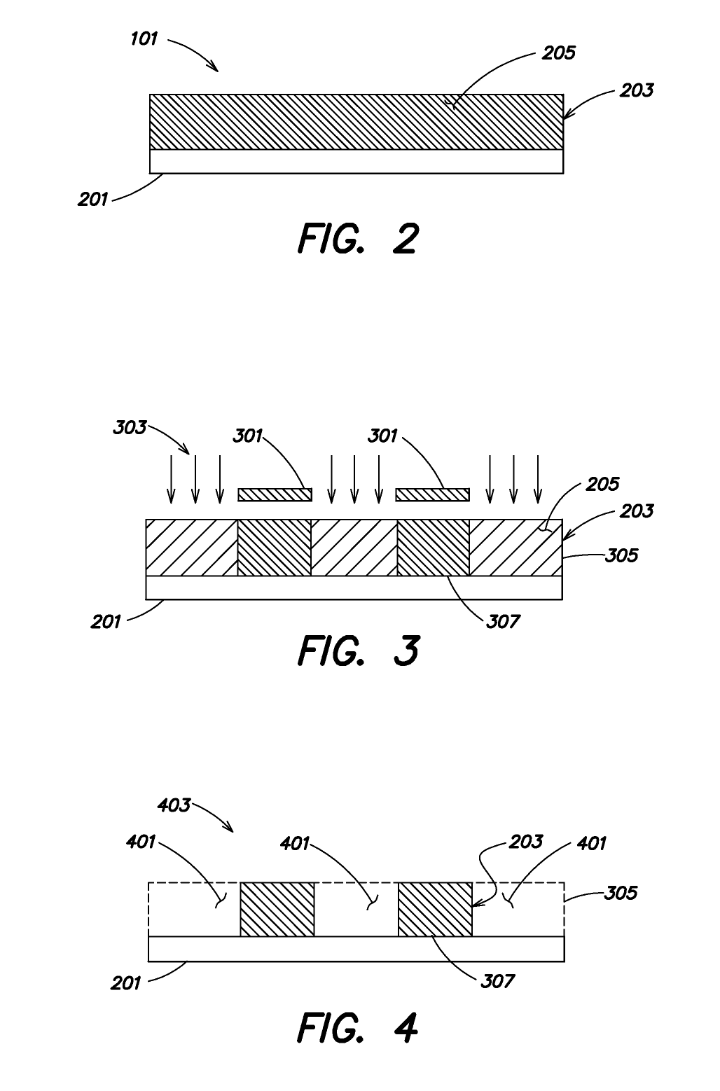

In step 107, a substrate is provided. For example, the substrate may include glass, triacetylcellulose (TAC), polycarbonate (PC), polyethersulfone (PES), polyethylenetherephtalate (PET), polyethylenenaphthalate (PEN), polyvinylalcohol (PVC), polymetylmethacrylate (PMMA), cyclo-olefin polymer (COP) and/or another suitable material. FIG. 2 is a side, cross-sectional view of a substrate 201 that may be processed in accordance with the method 101.

In step 109, a layer 203 (FIG. 2) of black matrix composition 205 may be formed on the substrate 201. An immersing method, a spraying method, a rotating and spin-coating method or another suitable method may be employed to form the black matrix composition layer 203 on the substrate 201. In this manner, the substrate 201 may be coated with the black matrix composition 205. The substrate 201 may be heated to dry the black matrix composition 205. Consequently, solvent in the black matrix composition 205 may be evaporated. Such a method of post-coating heating may be referred to as a “soft bake” process.

In step 111, activation energy may be applied to the black matrix composition 205 to polymerize the wetting additive and thus, polarize the molecules of the wetting additive such that the ink-phobic portions of the molecules migrate toward the activation energy. The polymerization may be achieved using any practicable activation energy source depending on the composition 205. For example, ultra violet light, electron beam radiation, laser light, and/or a lamp may be used as an activation energy source. Other activation energy sources or combinations may be used.

In some embodiments, in step 111, the layer 203 of back matrix composition may be patterned. For example, as shown in FIG. 3, a mask 301 may be placed over (or formed on) the black matrix composition layer 203. Thereafter, UV or other wavelength light or energy 303 may be used to irradiate the black matrix composition layer 203 through the mask 301. The energy 303 may expose portions 305 of the black matrix composition layer 203, but does not expose other portions 307 of the black matrix composition layer 203. Note that in alternative embodiments, a negative mask may be employed in which opposite portions 307 of the black matrix composition layer 203 may be exposed to energy 303.

When light (or other energy) of an appropriate wavelength strikes a portion of the black matrix composition layer 203, the initiator in the black matrix composition 205 may absorb the light 303 (energy) to form a free radical molecule in the exposed portion. The initiator may function as a polymerization initiator for polymerizing the polymerizable monomers in the exposed portion of the black matrix composition layer 203. Therefore, such exposed portion of the black matrix composition layer 203 may include polymers resulting from polymerization of the polymerizable monomers. The polymerizable monomers of the wetting additive may lock in upon such lithographic exposure.

Following exposure, a developing step may be performed on the substrate 201. For example, a developing solution may be employed to develop the exposed or unexposed portion of the black matrix composition layer 203 so that such portion is removed. For example, the binder resin included in the exposed portion may react with the developing solution. FIG. 4 is an example of a cross sectional view of the substrate 201 following developing.

Voids resulting from removal of the developed portions may serve as pixel areas or wells 401 into which ink may be injected, via ink jetting, when forming a color filter and that define the black matrix 403.

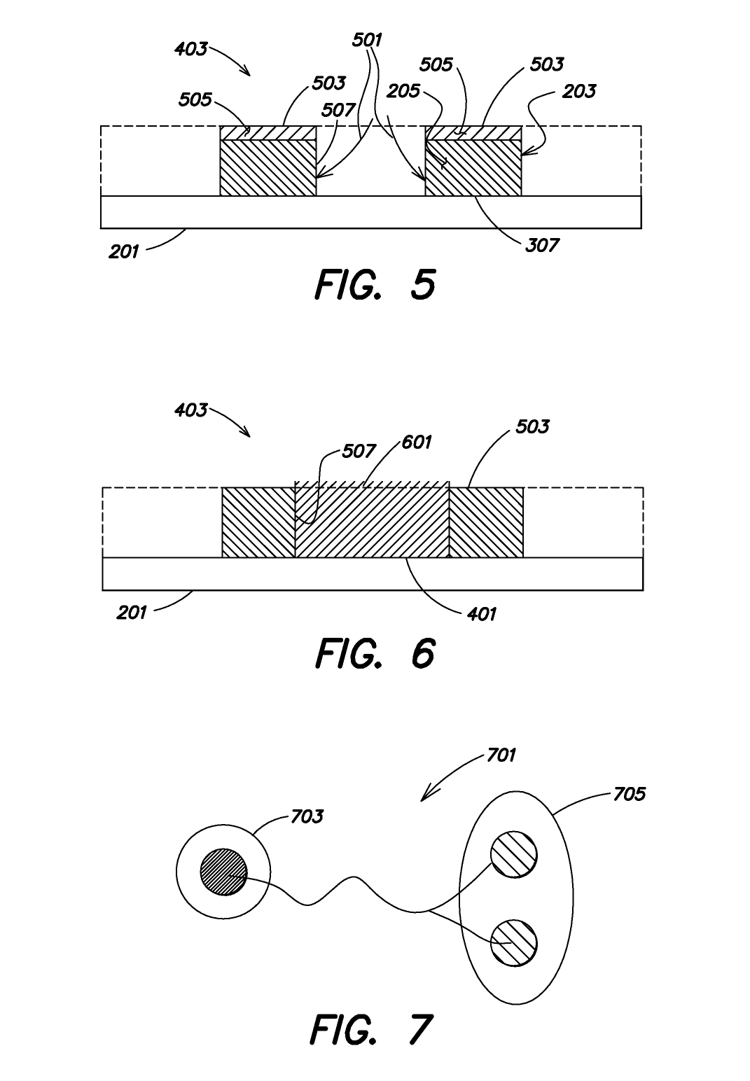

The substrate 201 may be further cured. For example, the substrate 201 may be heated or exposed to ultra violet light, electron beam radiation, laser light, etc. such that the black matrix composition in the layer 203 may cure and cross-link to form a cross-linked resin in the black matrix composition layer 203. As shown in FIG. 5, when the black matrix composition layer 203 is subjected to energy 501, the ink-phobic non-polar portion of the wetting additive molecules may rise to a top surface 503 of the black matrix composition layer 203, and form an ink-phobic layer 505 near the top surface 503 of the black matrix composition layer 203. This ink-phobic layer 505 may be relatively ink-phobic (e.g., more ink-phobic than the black matrix material that includes a lower concentration or no amount of the wetting additive).

In this manner, the top surface 503 of the black matrix 403 may be ink-phobic and sidewalls surfaces 507 of each pixel well formed in the black matrix (e.g., adjacent the pixel areas 401) may be less ink-phobic than the top surface 503, and in some embodiments, even ink-philic. Consequently, the top surface 503 of the black matrix may prevent bleeding of ink between adjacent pixel wells, and therefore, may prevent intermixing of ink colors during jetting processes as well as help improve the fill profiles of the pixel wells (e.g., more consistent and complete filling of the pixel wells). An improved color filter thereby may be produced. For example, FIG. 6 is a cross-sectional side view of ink 601 in the pixel area 401 of the substrate 201 in accordance with an embodiment of the present invention. With reference to FIG. 6, the wetting additive concentrated at the top surface 503 of the black matrix 403 following curing renders the top surface 503 ink-phobic, while sidewall surfaces 507 remain less ink-phobic, even ink-philic. Thus, the ink 601 may bead away from the top surface 503 of the black matrix 403 so that the ink 601 does not spread beyond the pixel area 401.

In practice, the migration of the wetting additive may be a dynamic process that happens during the entire pixel well formation process (e.g., during formation of a black matrix composition layer on a substrate, during soft bake, during any UV curing process, etc.). In at least one embodiment, the soft bake time may be about 1.5 minutes at a temperature of about 105° C. (in air). UV curing (exposure) may be about 30-60 seconds in air, and the final cure may be about 10 minutes in air. Other soft bake, UV curing, and/or final cure times may employed, as may other bake and/or cure gas environments (e.g., nitrogen, argon, etc.).

FIG. 7 illustrates an exemplary molecule 701 that may be employed as a wetting additive in accordance with an embodiment of the present invention. With reference to FIG. 7, the exemplary molecule 701 may include a first end 703 that may be ink-philic and/or reactive. Further, the exemplary molecule 701 may include a second end 705 that may be ink-phobic.

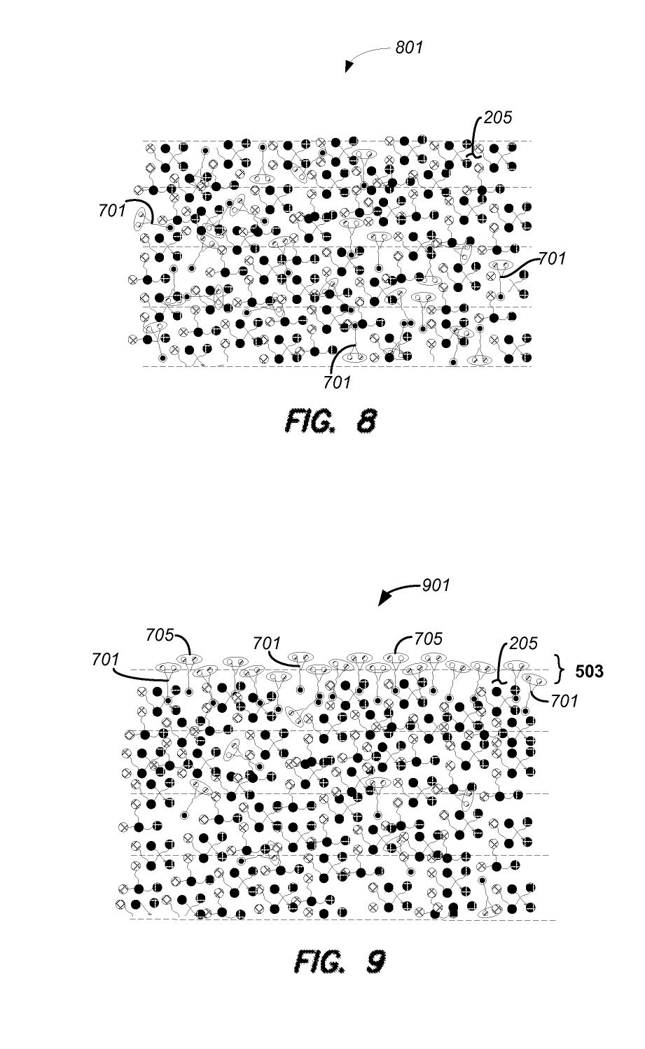

FIG. 8 illustrates a pre-cure (e.g., prior to application of activation energy) orientation 801 of the exemplary molecules 701 of FIG. 7 in the black matrix composition 205 in accordance with an embodiment of the present invention. With reference to FIG. 8, in the pre-cure orientation 801, the first and second ends 703, 705 of the molecules 701 may be approximately randomly oriented, and the molecules may be distributed approximately uniformly through the black matrix composition 205.

FIG. 9 illustrates a post-cure (e.g., subsequent to application of activation energy) orientation 901 of the exemplary molecules 701 of FIG. 7 in the black matrix composition 205 in accordance with an embodiment of the present invention. With reference to FIG. 9, during curing of the black matrix material, molecules 701 rise to a top surface 503 of the black matrix composition 205 with the ink-phobic end 705 of the molecules 701 located at or near the top surface 503 (e.g., the surface exposed to the activation energy) so as to form the previously described ink-phobic layer 505. Therefore, the top surface 503 is more ink-phobic than any sidewalls formed within the black matrix material.

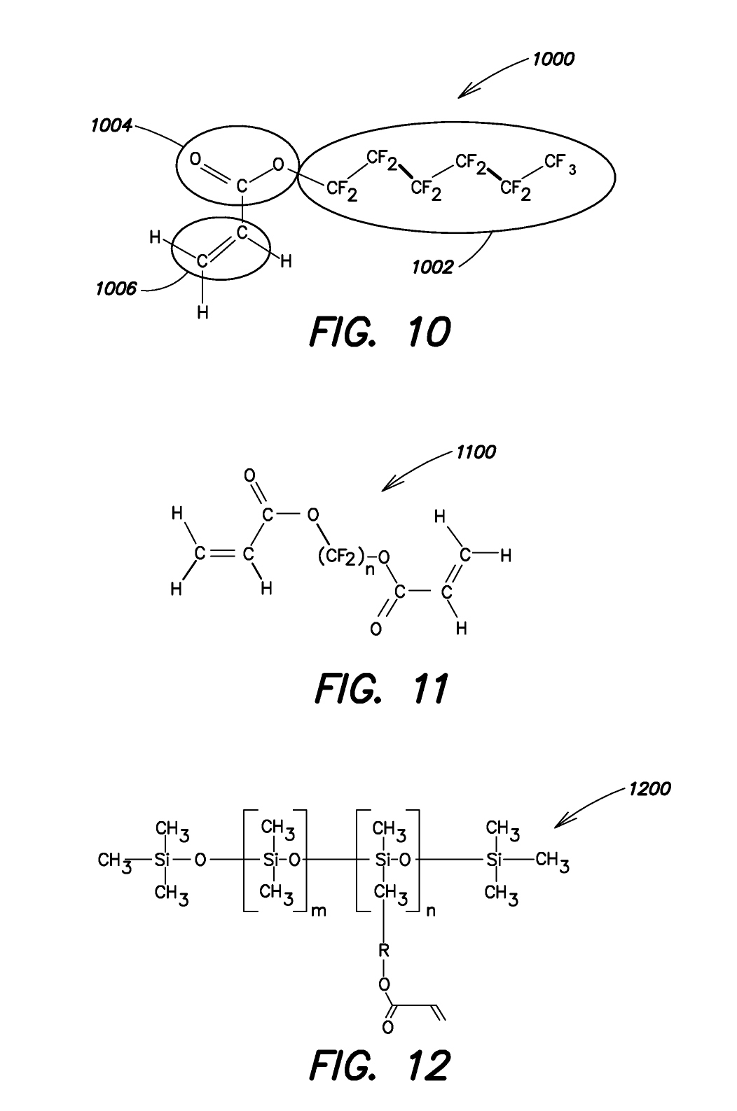

Turning now to FIGS. 10 to 12, structural formulas of three specific examples of polymerizable molecules suitable for use as wetting additives according to the present invention are depicted. FIG. 10 depicts a structural formula of an example wetting additive molecule 1000 (e.g., acrylate) with a non-polar tail portion 1002 that includes a CF₂ chain which is ink-phobic. The polar portion 1004 includes a carbonyl carbon atom double bonded to a first oxygen atom and single bonded to a second oxygen atom. The polar portion 1004 is ink-philic. The molecule 1000 further includes a polymerizable portion 1006 that is also directly attached to the carbonyl carbon atom of the polar portion 1004. The polymerizable portion 1006 includes two carbon atoms that are double bonded to each other. FIG. 11 depicts a structural formula of an example wetting additive molecule 1100 with a non-polar body portion. FIG. 12 depicts a structural formula of an example silicon polymer wetting additive molecule 1200.

A conventional black matrix material formulation may include conventional ingredients such as a monomer, oligomer/polymer, photoinitiator, pigments, solvents, etc. Ink landing on such black matrix material may typically result in an ink contact angle on the top surface of the black matrix which is less than about 5 degrees. In contrast, inclusion of the additive(s) of the present invention may be used to change the ink contact angle on the top surface of the black matrix from approximately 10 to approximately 75 degrees, and more preferably from approximately 25 to approximately 60 degrees. The concentration of the additive used and the processing conditions (e.g., activation/exposure time and energy, other ingredients, etc.) may be used to adjust the contact angle to a more specific desired value within the above ranges (e.g., approximately 28 degrees, approximately 35 degrees, etc.).

The foregoing description discloses only exemplary embodiments of the invention. Modifications of the above disclosed apparatus and methods which fall within the scope of the invention will be readily apparent to those of ordinary skill in the art. For instance, concentrations of the pigment dispersion, initiator, polymerizable monomer, binder resin and/or solvent in the black matrix composition may be varied. Also, in some embodiments, the black matrix may be formed directly on the thin film transistor (TFT) layer of the flat panel display. Further, the present invention may also be applied to processes for spacer formation, polarizer coating, and nanoparticle circuit forming.

Accordingly, while the present invention has been disclosed in connection with exemplary embodiments thereof, it should be understood that other embodiments may fall within the spirit and scope of the invention, as defined by the following claims.

The invention claimed is:

1. A black matrix composition for use in forming a color filter for a flat-panel display, comprising:
an additive including polymerizable molecules, the polymerizable molecules each including polar portions and non-polar portions, and wherein the non-polar portions are ink-phobic.

2. The black matrix composition of claim 1 wherein the non-polar portions of the polymerizable molecules migrate toward a surface of the black matrix composition upon the surface being exposed to an activation energy.

3. The black matrix composition of claim 1 wherein the polar portions of the polymerizable molecules are ink-philic relative to the non-polar portions.

4. The black matrix composition of claim 1 wherein the additive includes at least one of: a fluorinated acrylate monomer; a fluorinated acrylate oligomer; a silicone-group-contained acrylate monomer; a silicone-group-contained acrylate oligomer; a hydrophobic-group-contained acrylate monomer; a hydrophobic-group-contained acrylate oligomer; reactive wax; and fluorosilanes.

5. The black matrix composition of claim 1 further comprising at least one of:
a pigment dispersion;
an initiator;
a polymerizable monomer or oligomer;
a binder resin; and
a solvent.

6. The black matrix composition of claim 1 wherein the black matrix composition includes the additive in a concentration range from approximately 100 parts per million by weight to approximately 10,000 parts per million by weight of the black matrix composition not including any solvent.

7. The black matrix composition of claim 1 wherein the additive has a molecular weight in a range from approximately 100 Mw to approximately 100,000 Mw weight average molecular weight.

8. A coated substrate for use in forming a color filter for a flat-panel display, comprising:
a substrate; and
a layer of black matrix composition formed on the substrate, wherein the black matrix composition includes polymerizable molecules, the polymerizable molecules each including polar portions and non-polar portions, and wherein the non-polar portions are ink-phobic.

9. The coated substrate of claim 8 wherein the non-polar portions of the polymerizable molecules migrate toward a surface of the black matrix composition upon the surface being exposed to an activation energy.

10. The coated substrate of claim 8 wherein the polar portions of the polymerizable molecules are ink-philic relative to the non-polar portions.

11. The coated substrate of claim 8 wherein the polymerizable molecules include at least one of: a fluorinated acrylate monomer; a fluorinated acrylate oligomer; a silicone-group-contained acrylate monomer; a silicone-group-contained acrylate oligomer; a hydrophobic-group-contained acrylate monomer; a hydrophobic-group-contained acrylate oligomer; reactive wax; and fluorosilanes.

12. The coated substrate of claim 8 wherein the black matrix composition further comprises at least one of:
a pigment dispersion;
an initiator;
a polymerizable monomer or oligomer;
a binder resin; and
a solvent.

13. The coated substrate of claim 8 wherein the black matrix composition includes the polymerizable molecules in a concentration range from approximately 100 parts per million by weight to approximately 10,000 parts per million by weight of the black matrix composition not including any solvent.

14. The coated substrate of claim 8 wherein the polymerizable molecules have a molecular weight in a range from approximately 100 Mw to approximately 100,000 Mw weight average molecular weight.

15. A method of forming a color filter for a flat-panel display, comprising:
forming a black matrix composition including polymerizable molecules, the polymerizable molecules each including polar portions and non-polar portions, and wherein the non-polar portions are ink-phobic;
providing a substrate;
forming a layer of the black matrix composition on the substrate; and
applying activation energy to the black matrix composition on the substrate.

16. The method of claim 15 wherein forming a black matrix composition further includes forming a black matrix composition in which the non-polar portions of the polymerizable molecules migrate toward a surface of the black matrix composition in response to applying activation energy to the black matrix composition.

17. The method of claim 15 wherein forming a black matrix composition further includes forming a black matrix composition in which the polar portions of the polymerizable molecules are ink-philic relative to the non-polar portions.

18. The method of claim 15 wherein forming a black matrix composition further includes forming a black matrix composition in which the polymerizable molecules include at least one of: a fluorinated acrylate monomer; a fluorinated acrylate oligomer; a silicone-group-contained acrylate monomer; a silicone-group-contained acrylate oligomer; a hydrophobic-group-contained acrylate monomer; a hydrophobic-group-contained acrylate oligomer; reactive wax; and fluorosilanes.

19. The method of claim 15 wherein forming a black matrix composition further includes forming a black matrix composition in which the black matrix composition further comprises at least one of:
a pigment dispersion;
an initiator;
a polymerizable monomer or oligomer;
a binder resin; and
a solvent.

20. The method of claim 15 wherein forming a black matrix composition further includes forming a black matrix composition in which the polymerizable molecules are present in a concentration range from approximately 100 parts per million by weight to approximately 10,000 parts per million by weight of the black matrix composition not including any solvent.

21. The method of claim 15 wherein forming a black matrix composition further includes forming a black matrix composition in which the polymerizable molecules have a molecular weight in a range from approximately 100 Mw to approximately 100,000 Mw weight average molecular weight.

22. The method of claim 15 wherein applying activation energy to the black matrix composition includes applying electron beam radiation to the black matrix composition.

23. The method of claim 15 further comprising patterning a matrix in the black matrix composition.

24. The method of claim 23 wherein applying activation energy to the black matrix composition includes polymerizing the black matrix composition such that a top surface of the matrix is ink-phobic and side surfaces of the matrix are ink-philic.
